(19) United States
(12) Patent Application Publication
(10) Pub. No.: US 2012/0268218 A1
(43) Pub. Date: Oct. 25, 2012

(54) VIBRATION CIRCUIT

(75) Inventor: Toru WATANABE, Matsumoto (JP)

(73) Assignee: SEIKO EPSON CORPORATION, Tokyo (JP)

(21) Appl. No.: 13/449,954

(22) Filed: Apr. 18, 2012

(30) Foreign Application Priority Data
Apr. 20, 2011 (JP) 2011-094049

(51) Int. Cl. H03B 5/36

(52) U.S. Cl. 331/116 R

(57) ABSTRACT

A vibration circuit includes: a micro electro mechanical systems (MEMS) vibrator which includes a first electrode and a second electrode which are arranged with a gap therebetween; an amplification section which includes a gain section which has a first input terminal and a first output terminal and of which gain is greater than 1, and a gain restriction section which includes a second input terminal and a second output terminal and of which the gain is less than 1; and an output terminal which is connected to the first output terminal, wherein the first electrode is connected to the first input terminal, wherein the first output terminal is connected to the second input terminal, and wherein the second output terminal is connected to the second electrode.

### BACKGROUND

1. Technical Field

The present invention relates to a vibration circuit.

2. Related Art

Micro electro mechanical systems (MEMS) correspond to one of the micro-structure forming technologies, and refer to, for example, a technology which manufactures a minute electronic mechanism system of micron order or the product thereof. A vibration element (MEMS vibrator) manufactured using the MEMS technology has been developed. Further, a vibration circuit which uses the MEMS vibrator has been developed. JP-A-2009-200888 discloses a vibrator which uses the MEMS vibrator.

Compared to a crystal vibrator or a ceramic vibrator, the MEMS vibrator has a passage characteristic which is easily distorted when a signal having a high voltage is input as an input signal. If the passage characteristic is distorted, a phenomenon in which frequency is disturbed (frequency is unstable) is easily generated.

### SUMMARY

An advantage of some of the aspects of the invention is to provide a vibration circuit in which the disturbance of the frequency of an output signal is restricted.

An aspect of the invention is directed to an vibration circuit including a micro electro mechanical systems (MEMS) vibrator which includes a first electrode and a second electrode which are arranged with a gap therebetween, an amplification section which includes a gain section which has a first input terminal and a first output terminal and of which gain is greater than 1, and a gain restriction section which includes a second input terminal and a second output terminal and of which the gain is less than 1; and an output terminal which is connected to the first output terminal. The first electrode is connected to the first input terminal. The first output terminal is connected to the second input terminal. The second output terminal is connected to the second electrode.

The meaning of the term “connected” is “electrically connected” and includes “connected in an alternating-current manner” in addition to “connected in a direct-current manner”.

According to the aspect of the invention, since a signal which is input to the MEMS vibrator is the output signal of the gain restriction section of which the gain is less than 1, it is difficult to distort a passage characteristic. Therefore, it is possible to realize the vibration circuit in which the disturbance of the frequency of the output signal is restricted.

Further, according to the aspect of the invention, since the output signal of the gain section in which the gain is greater than 1 becomes the output signal of the vibration circuit, it is possible to output a signal in which an amplitude is large.

In the vibration circuit according to the aspect of the invention, the vibration circuit may further include a voltage application section which applies a bias voltage between the first electrode and the second electrode; and a control section which controls the gain restriction section and the voltage application section. The control section may perform control by associating the gain of the gain restriction section with the bias voltage applied by the voltage application section.

In the MEMS vibrator, the degree of the distortion of the passage characteristic changes based on the amplitude of the bias voltage. According to the aspect of the invention, it is possible to realize the vibration circuit in which the disturbance of the frequency of the output signal is further restricted in such a way that the control section performs control by associating the gain of the gain restriction section with the bias voltage applied by the voltage application section.

In the vibration circuit according to the aspect of the invention, the control section may perform control such that the gain of the gain restriction section decreases as the bias voltage applied by the voltage application section increases.

The MEMS vibrator has a tendency in that the passage characteristic is easily distorted as the bias voltage becomes high. According to the aspect of the invention, the control section performs control such that the gain of the gain restriction section becomes small as the bias voltage applied by the voltage application section becomes high, so that it is possible to realize the vibration circuit in which the disturbance of the frequency of the output signal is further restricted.

### BRIEF DESCRIPTION OF THE DRAWINGS

The invention will be described with reference to the accompanying drawings, wherein like numbers reference like elements.

FIG. 1 is a circuit diagram illustrating a vibration circuit according to a first embodiment.

FIG. 2 is a circuit diagram illustrating an example of an amplification section.

FIG. 3 is a graph schematically illustrating the passage characteristics of a MEMS vibrator.

FIG. 4 is a circuit diagram illustrating a vibration circuit according to a second embodiment.

FIG. 5 is a circuit diagram illustrating an example of a voltage application section.

FIG. 6 is a circuit diagram illustrating an example of a gain restriction section.

FIG. 7 is a graph schematically illustrating the passage characteristics of the MEMS vibrator.

FIG. 8 is a plan view schematically illustrating an example of the configuration of the MEMS vibrator.

FIG. 9 is a cross-sectional view schematically illustrating the example of the configuration of the MEMS vibrator.

### DESCRIPTION OF EXEMPLARY EMBODIMENTS

Hereinafter, preferred embodiments of the invention will be described in detail with reference to the accompanying drawings. Meanwhile, the embodiments which will be described below do not illegally limit the content of the invention disclosed in the above-described aspects. Further, all of the configurations which are described below are not limited as the essential configuration requirements of the invention.

### 1. Vibration Circuit According to First Embodiment

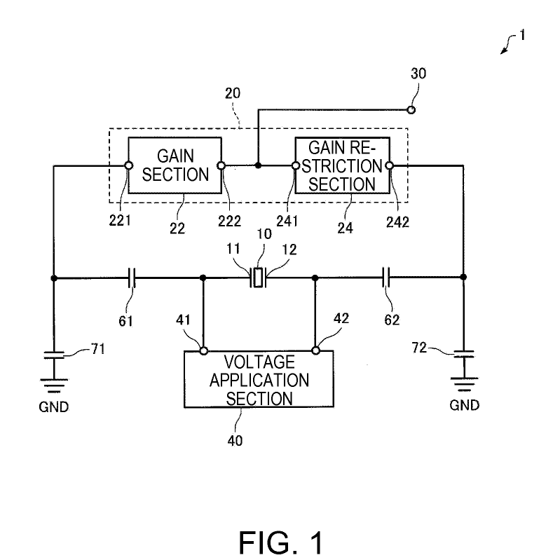

FIG. 1 is a circuit diagram illustrating a vibration circuit 1 according to a first embodiment.

The vibration circuit 1 according to the first embodiment includes a MEMS vibrator 10 having a first electrode 11 and a second electrode 12 which are arranged with a gap therebetween, an amplification section 20 having a gain section 22, which includes a first input terminal 221 and a first output terminal 222 and in which a gain is greater than 1, and a gain restriction section 24 which includes a second input terminal 241 and a second output terminal 242 and in which the gain is less than 1, an output terminal 30 connected to the first output terminal 222. The first electrode 11 is connected to the first input terminal 221, the first output terminal 222 is connected to the second input terminal 241, and the second output terminal 242 is connected to the second electrode 12.

In the first embodiment, MEMS vibrator 10 is an electrostatic-type MEMS vibrator which includes the first electrode 11 and the second electrode 12 which are arranged with a gap therebetween. An example of the configuration of the MEMS vibrator 10 will be described in detail in “3. Example of configuration of MEMS vibrator”.

The amplification section 20 amplifies a signal with gain which is greater than 1 such that a predetermined vibration condition is satisfied. The amplification section 20 may be configured by combining a plurality of inverter circuits (inverting circuits) with amplifier circuits. In the example shown in FIG. 1, the amplification section 20 is configured in such a way that the gain section 22 in which the gain is greater than 1 is connected in series to the gain restriction section 24 in which the gain is less than 1.

In the example shown in FIG. 1, the first electrode 11 of the MEMS vibrator 10 is connected to the first input terminal 221 of the gain section 22, the first output terminal 222 of the gain section 22 is connected to the second input terminal 241 of the gain restriction section 24, and the second output terminal 242 of the gain restriction section 24 is connected to the second electrode 12 of the MEMS vibrator 10. Further, the output terminal 30 is connected to the first output terminal 222 of the gain section 22 and the second input terminal 241 of the gain restriction section 24.

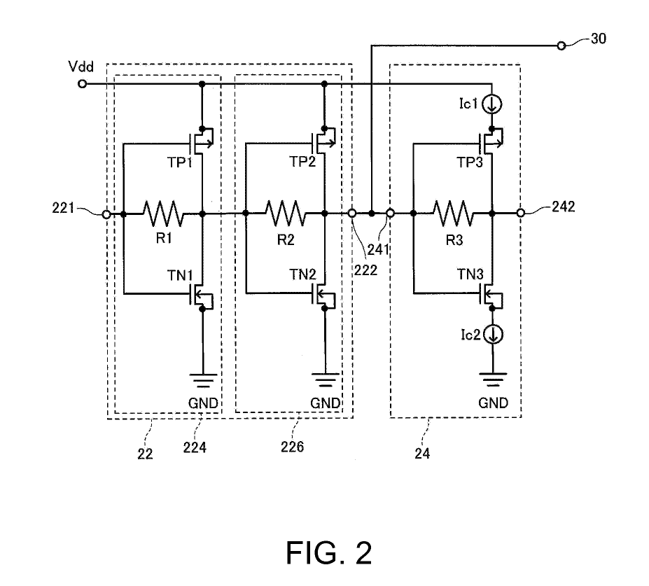

FIG. 2 is a circuit diagram illustrating an example of the amplification section 20.

In the example shown in FIG. 2, the gain section 22 is configured in such a way that an inverter circuit 224 is connected to an inverter circuit 226 in series. The inverter circuit 224 includes a PMOS transistor TP1 and an NMOS transistor TN1 which are connected in series between power supply potential Vdd and ground potential GND. The gates of the PMOS transistor TP1 and the NMOS transistor TN1 are mutually connected. The inverter circuit 226 includes a PMOS transistor TP2 and an NMOS transistor TN2 which are connected in series between the power supply potential Vdd and the ground potential GND. The gates of the PMOS transistor TP2 and the NMOS transistor TN2 are mutually connected.

In the example shown in FIG. 2, the gain restriction section 24 is configured with an inverter circuit which is configured to sequentially include a constant current source Ic1, a PMOS transistor TP3, an NMOS transistor TN3, and a constant current source Ic2 which are connected in series between the power supply potential Vdd and the ground potential GND, and configured such that the gates of the PMOS transistor TP3 and the NMOS transistor TN3 are mutually connected. Setting can be made such that the gain of the gain restriction section 24 is less than 1 by arbitrarily setting the current values of the constant current source Ic1 and the constant current source Ic2.

The vibration circuit 1 according to the first embodiment may be configured to include a feedback resistor corresponding to the amplification section 20. In the example shown in FIG. 2, the input terminal and the output terminal of the inverter circuit 224 are connected via a resistor R1, the input terminal and the output terminal of the inverter circuit 226 are connected via a resistor R2, and the second input terminal 241 and the second output terminal 242 of the gain restriction section 24 are connected via a resistor R3.

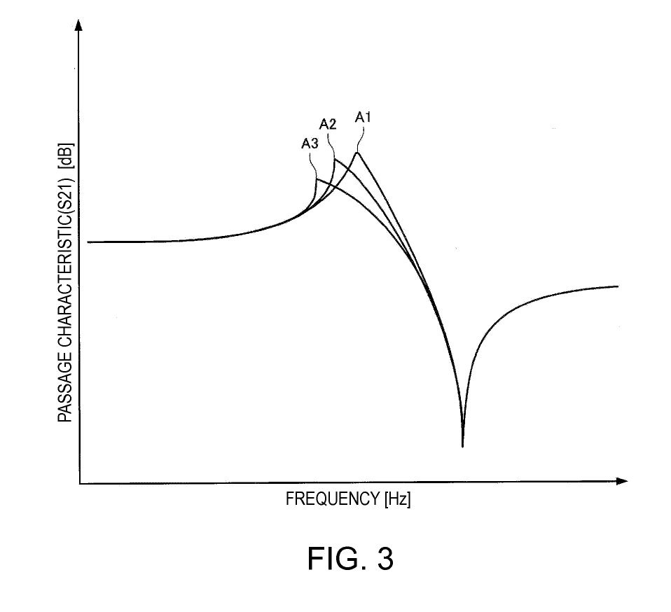

FIG. 3 is a graph schematically illustrating the passage characteristics of the MEMS vibrator 10. A horizontal axis indicates the frequency of an input signal and a vertical axis indicates the passage characteristic of an S parameter (S21). Further, when the power of the input signal is power P1, the passage characteristic corresponds to a passage characteristic A1. When the power of the input signal is power P2, the passage characteristic corresponds to a passage characteristic A2. When the power of the input signal is power P3, the passage characteristic corresponds to passage characteristic A3. Further, the magnitude relation of power P1<power P2<power P3 is established.

As shown in FIG. 3, when the power P1 corresponds to power within a power range in which the MEMS vibrator 10 can be linearly operated, the passage characteristic A1 has a symmetrical form in the vicinity of a resonance frequency (frequency at which the passage characteristic is maximized) with respect to the increase and decrease of the frequency.

However, when the power P2 and the power P3 correspond to high power which exceeds the power range in which the MEMS vibrator 10 can linearly operate, the passage characteristic A2 and the passage characteristic A3 correspond to a resonance frequency which is different from that of the passage characteristic A1. In the example shown in FIG. 3, the resonance frequencies of the passage characteristic A2 and the passage characteristic A3 correspond to a frequency which is smaller than that of the passage characteristic A1. Further, each of the passage characteristic A2 and the passage characteristic A3 has an asymmetrical form in the vicinity of the resonance frequency with respect to the increase and decrease of the frequency.

Further, when the power P2 and the power P3 correspond to the high power which exceeds the power range in which the MEMS vibrator 10 can be linearly operated, the loss of the MEMS vibrator 10 becomes large. In the example shown in FIG. 3, the maximum values of the passage characteristic A2 and the passage characteristic A3 are less than the maximum value of the passage characteristic A1.

As described above, when a signal, which corresponds to the high power which exceeds the power range in which the MEMS vibrator 10 can be linearly operated, is input to the MEMS vibrator 10, the passage characteristic may be easily distorted. When the passage characteristic is distorted, it causes the frequency of the output signal of the vibration circuit to be disturbed (frequency is unstable).

According to the vibration circuit 1 according to the first embodiment, a signal input to the MEMS vibrator 10 corresponds to the output signal of the gain restriction section 24 in which the gain is less than 1, so that it is difficult to distort the passage characteristic. Therefore, a vibration circuit in which the disturbance of the frequency of the output signal is restricted can be implemented.

Further, according to the vibration circuit 1 according to the first embodiment, the output signal of the gain restriction section 22 in which the gain is greater than 1 becomes the output signal of the vibration circuit, so that it is possible to output a signal which has large amplitude.

The vibration circuit 1 according to the first embodiment may include a voltage application section 40 which applies a bias voltage between the first electrode 11 and the second electrode 12 of the MEMS vibrator 10. In the example shown in FIG. 1, the voltage application section 40 includes a first voltage terminal 41 and a second voltage terminal 42. The first voltage terminal 41 is connected to the first electrode 11 of the MEMS vibrator 10, and the second voltage terminal 42 is connected to the second electrode 12 of the MEMS vibrator 10.

When the electrostatic-type MEMS vibrator is used as the MEMS vibrator 10, it is necessary to provide electrical potential difference (bias voltage) between the electrodes included in the MEMS vibrator. In the example shown in FIG. 1, it is possible to apply a bias voltage between the first electrode 11 and the second electrode 12 of the MEMS vibrator 10 in such a way that the voltage application section 40 generates the electrical potential difference between the first voltage terminal 41 and the second voltage terminal 42.

The first electrode 11 of the MEMS vibrator 10 may be connected to the first input terminal 221 of the gain section 22 via a capacity 61. Further, the second electrode 12 of the MEMS vibrator 10 may be connected to the second output terminal 242 of the gain restriction section 24 via the capacity 62. Therefore, it is possible to prevent unnecessary electrical potential difference from being applied between the first input terminal 221 of the gain section 22 and the second output terminal 242 of the gain restriction section 24.

The vibration circuit 1 according to the first embodiment may include a capacity 71 which is connected between the first electrode 11 of the MEMS vibrator 10 and the ground potential GND and a capacity 72 which is connected between the second electrode 12 of the MEMS vibrator 10 and the ground potential GND.

According to the above-described vibration circuit 1, the MEMS vibrator 10, the capacity 71, and the capacity 72 can be used as the vibration circuit included in the resonance circuit.

### 2. Vibration Circuit According to Second Embodiment

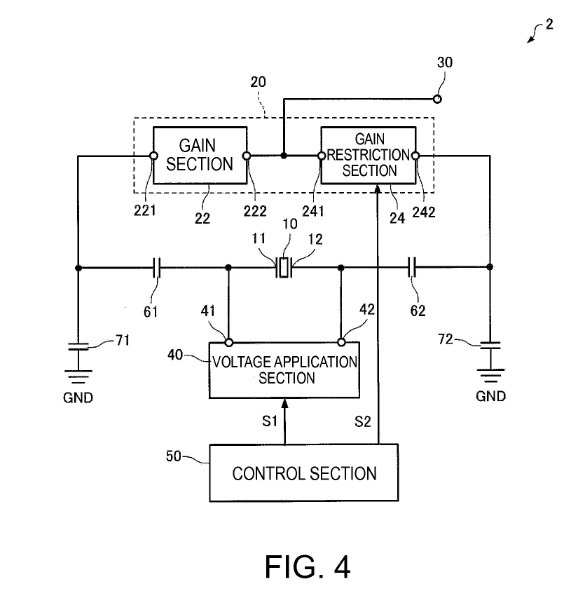

FIG. 4 is a circuit diagram illustrating a vibration circuit 2 according to a second embodiment. Hereinafter, components which are different from those of the vibration circuit 1 according to the first embodiment will be described in detail, and the same reference numerals are used for the same components as those of the vibration circuit 1 according to the first embodiment and the description thereof will be omitted.

The vibration circuit 2 according to the second embodiment includes a voltage application section 40 which applies a bias voltage between a first electrode 11 and a second electrode 12, and a control section 50 which controls a gain restriction section 24 and a voltage application section 40. The control section 50 performs control by associating the gain of the gain restriction section 24 with the bias voltage applied by the voltage application section 40.

In the example shown in FIG. 4, the control section 50 controls the bias voltage applied by the voltage application section 40 by outputting a control signal S1 to the voltage application section 40. Further, in the example shown in FIG. 4, the control section 50 controls the gain of the gain restriction section 24 by outputting a control signal S2 to the gain restriction section 24.

Meanwhile, in the example shown in FIG. 4, although the control section 50 directly controls the gain restriction section 24 and the voltage application section 40, the control section 50 may indirectly control at least one of the gain restriction section 24 and the voltage application section 40. For example, the control section 50 may control the gain restriction section 24 via the voltage application section 40.

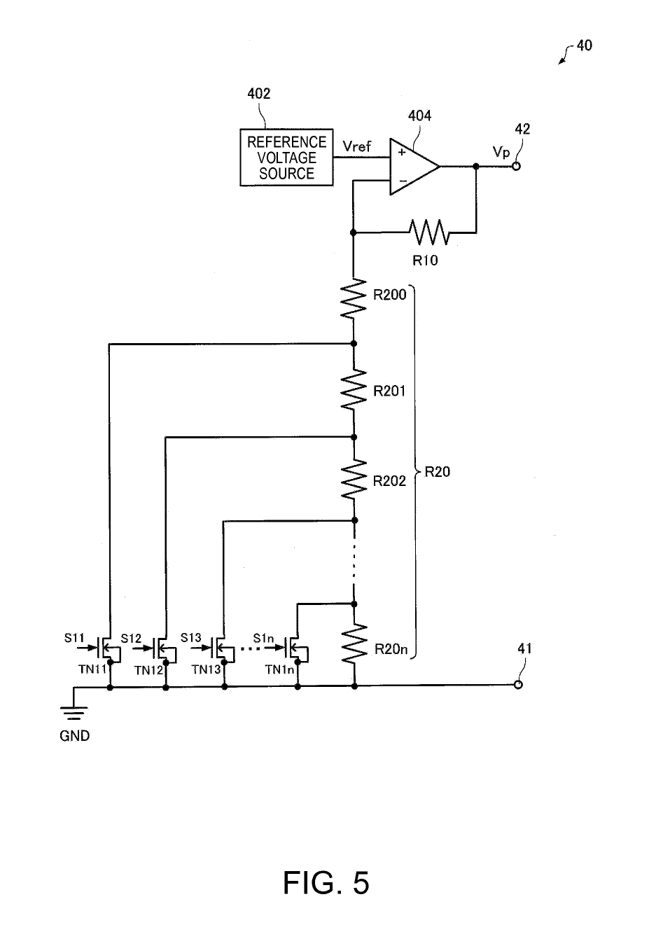

FIG. 5 is a circuit diagram illustrating an example of the voltage application section 40. In the example shown in FIG. 5, n-bit control signals are used as the control signal S1, and signals corresponding to the respective bits are indicated as S11, S12, S13, . . . , and S1n.

The voltage application section 40 shown in FIG. 5 includes a reference voltage source 402, an operation amplifier 404, a resistor R10, and a variable resistor R20. Further, the first voltage terminal 41 is connected to the ground potential GND, and the second voltage terminal 42 is connected to the output terminal of the operation amplifier 404.

The reference voltage source 402 generates a reference voltage Vref which is the reference of the bias voltage applied by the voltage application section 40. The non-inverted input terminal of the operation amplifier 404 is connected to the output terminal of the reference voltage source 402. That is, the reference voltage Vref generated by the reference voltage source 402 is input to the non-inverted input terminal of the operation amplifier 404. The inverted output terminal of the operation amplifier 404 is connected to the output terminal of the operation amplifier 404 via the resistor R10 and connected to the ground potential GND via the variable resistor R20.

The variable resistor R20 includes a resistor R200, a resistor R201, a resistor R202, . . . , and a resistor R20n which are sequentially connected in series from a side which is near to the non-inverted input terminal of the operation amplifier 404. Further, the variable resistor R20 includes an NMOS transistor TN11 which short-circuits the resistor R201 to resistor R20n to the ground potential GND, an NMOS transistor TN12 which short-circuits the resistor R202 to the resistor R20n to the ground potential GND, an NMOS transistor TN13 which short-circuits the resistor R203 (not shown) to the resistor R20n to the ground potential GND, . . . , and an NMOS transistor TN1n which short-circuits the resistor R20n−1 (not shown) to the resistor R20n to the ground potential GND.

The control signal S11 is input to the gate of the NMOS transistor TN11, the control signal S12 is input to the gate of the NMOS transistor TN12, the control signal S13 is input to the gate of the NMOS transistor TN13, . . . , and the control signal S1n is input to the gate of the NMOS transistor TN1n. Therefore, it is possible to select a resistor to be short-circuited from among the resistors R201 to R20n in response to the control signals S11 to S1n, so that the resistance of the variable resistor R20 can be changed.

Further, the output voltage Vp (bias voltage applied by the voltage application section 40) of the operation amplifier 404 is expressed using the following Equation.

Vp=(1+resistance of resistor R10/resistance of variable resistor R20)·Vref

Therefore, it is possible to change the bias voltage Vp applied by the voltage application section 40 by changing the resistance of the variable resistor R20.

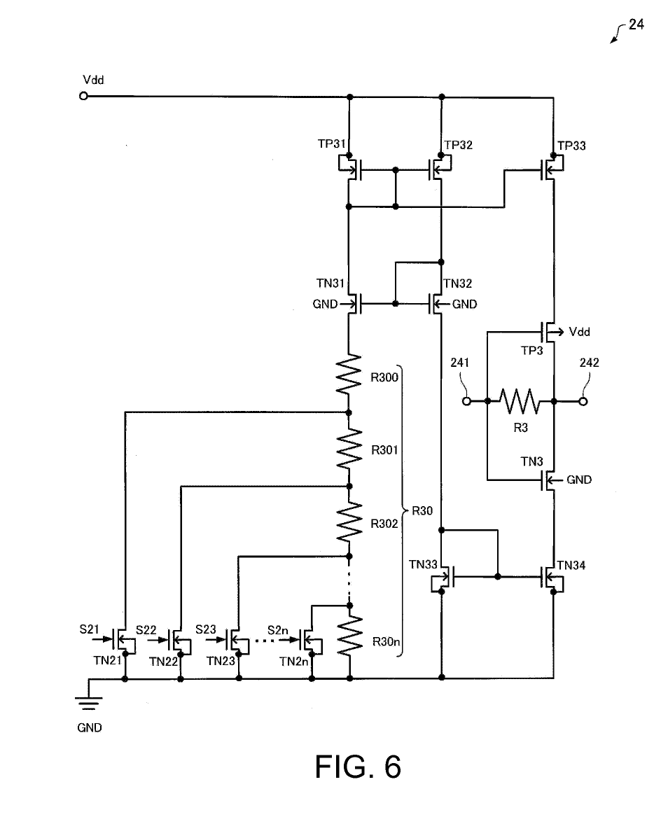

FIG. 6 is a circuit diagram illustrating an example of the gain restriction section 24. In the example shown in FIG. 6, n-bit control signals are used as the control signal S2, and signals corresponding to the respective bits are indicated as S21, S22, S23, . . . , and S2n.

The gain restriction section 24 shown in FIG. 6 includes PMOS transistors TP31 to TP33, NMOS transistors TN31 to TN34, and a variable resistor R30 instead of the constant current source Ic1 and the constant current source Ic2 which are shown in FIG. 2.

The source of the PMOS transistor TP31 is connected to the power supply potential Vdd, and the drain thereof is connected to the drain of the NMOS transistor TN31 and the gates of the PMOS transistors TP31 to TP33. The source of the NMOS transistor TN31 is connected to the ground potential GND via the variable resistor R30.

The source of the PMOS transistor TP32 is connected to the power supply potential Vdd, and the drain thereof is connected to the drain of the NMOS transistor TN32 and the gates of the NMOS transistors TN31 to TN32. The source of the NMOS transistor TN32 is connected to the drain of the NMOS transistor TN33 and the gates of the NMOS transistors TN33 to TN34. The source of the NMOS transistor TN33 is connected to the ground potential GND.

The source of the PMOS transistor TP33 is connected to the power supply potential Vdd, and the drain thereof is connected to the source of the PMOS transistor TP3. The drain of the NMOS transistor TN34 is connected to the NMOS transistor TN3, and the source thereof is connected to the ground potential GND.

That is, a current mirror circuit, in which current flowing along the PMOS transistor TP31 is mirrored to the PMOS transistors TP32 to TP33, is configured. A current mirror circuit, in which current flowing along the NMOS transistor TN32 is mirrored to the NMOS transistor TN31, is configured. A current mirror circuit, in which current flowing along the NMOS transistor TN33 is mirrored to the NMOS transistor TN34, is configured.

The variable resistor R30 includes a resistor R300, resistor R301, a resistor R302, . . . , and a resistor R30n which are sequentially connected in series from a side which is near to the source of the NMOS transistor TN31. Further, the variable resistor R30 includes an NMOS transistor TN21 which short-circuits the resistor R301 to resistor R30n to the ground potential GND, an NMOS transistor TN22 which short-circuits the resistor R302 to the resistor R30n to the ground potential GND, an NMOS transistor TN23 which short-circuits the resistor R303 (not shown) to the resistor R30n to the ground potential GND, . . . , and an NMOS transistor TN2n which short-circuits the resistor R30n−1 (not shown) to the resistor R30n to the ground potential GND.

The control signal S21 is input to the gate of the NMOS transistor TN21, the control signal S22 is input to the gate of the NMOS transistor TN22, the control signal S23 is input to the gate of the NMOS transistor TN23, . . . , and the control signal S2n is input to the gate of the NMOS transistor TN2n. Therefore, it is possible to select a resistor to be short-circuited from among the resistors R301 to R30n in response to the control signals S21 to S2n, so that the resistance of the variable resistor R30 can be changed.

Further, as the resistance of the variable resistor R30 becomes large, current which flows to the PMOS transistor 33 and current which flows to the NMOS transistor TN34 become small. Therefore, it is possible to change the gain of the gain restriction section 24 by changing the resistance of the variable resistor R30.

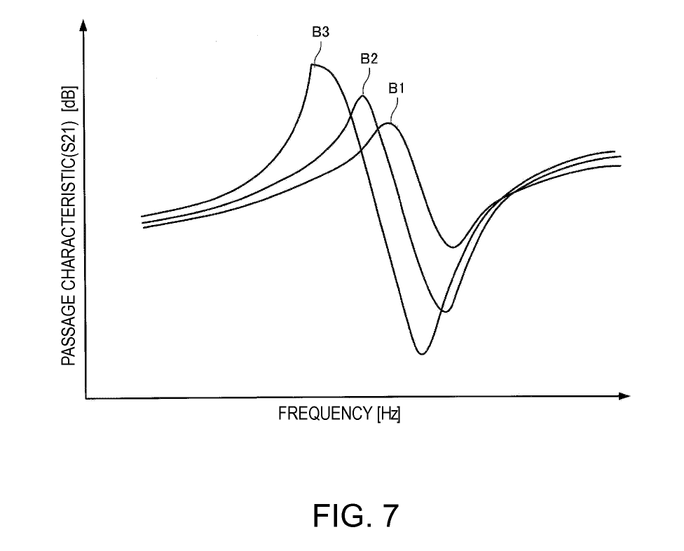

FIG. 7 is a graph schematically illustrating the passage characteristics of the MEMS vibrator 10. A horizontal axis indicates the frequency of an input signal, and a vertical axis indicates the passage characteristic of the S parameter (S21). Further, when the bias voltage is a voltage Vp1, the passage characteristic corresponds to a passage characteristic B1. When the bias voltage is a voltage Vp2, the passage characteristic corresponds to a passage characteristic B2. When the bias voltage is a voltage Vp3, the passage characteristic corresponds to a passage characteristic B3. Further, the magnitude relation of voltage Vp1<voltage Vp2<voltage Vp3 is established. Meanwhile, it is assumed that the power of each of the signals which are input to the MEMS vibrator 10 is the same.

As shown in FIG. 7, as the bias voltage increases, loss decreases. Therefore, the peak of the passage characteristic increases. Accordingly, the power of a signal which is input to the MEMS vibrator 10 increases.

As shown in FIG. 7, when the bias voltage is the voltage Vp1 or the voltage Vp2, the power of a signal which is input to the MEMS vibrator 10 becomes power which falls into the power range in which the MEMS vibrator 10 can linearly operate, and the passage characteristic B1 and the passage characteristic B2 have symmetrical forms in the vicinity of a resonance frequency (a frequency at which the passage characteristic is maximized) with respect to the increase and decrease of the frequency.

However, when the bias voltage is the voltage Vp3, the power of the signal which is input to the MEMS vibrator 10 becomes the high power which exceeds the power range in which the MEMS vibrator 10 can linearly operate. Therefore, the passage characteristic B3 has an asymmetrical form in the vicinity of the resonance frequency with respect to the increase and decrease of the frequency.

In the MEMS vibrator 10, the size of the loss changes based on the size of the bias voltage. Therefore, the degree of the distortion of the passage characteristic changes. According to the vibration circuit 2 according to the second embodiment, the control section 50 performs control by associating the gain of the gain restriction section 24 with the bias voltage applied by the voltage application section 40. Therefore, a vibration circuit in which the disturbance of the frequency of the output signal is further restricted can be implemented.

The control section 50 may perform control such that the gain of the gain restriction section 24 decreases as the bias voltage applied by the voltage application section 40 increases.

In the examples shown in FIGS. 5 and 6, the control section 50 performs control such that the resistance of the gain restriction section 24 of the variable resistor R30 increases as the resistance of the variable resistor R20 of the voltage application section 40 decreases.

As shown in FIG. 7, the MEMS vibrator 10 has a tendency in that the loss increases as the bias voltage increases, so that the passage characteristic is easily distorted. The control section 50 performs control such that the gain of the gain restriction section 24 decreases as the bias voltage applied by the voltage application section 40 increases. Therefore, a vibration circuit in which the disturbance of the frequency of the output signal is further restricted can be implemented.

### 3. Example of Configuration of MEMS Vibrator

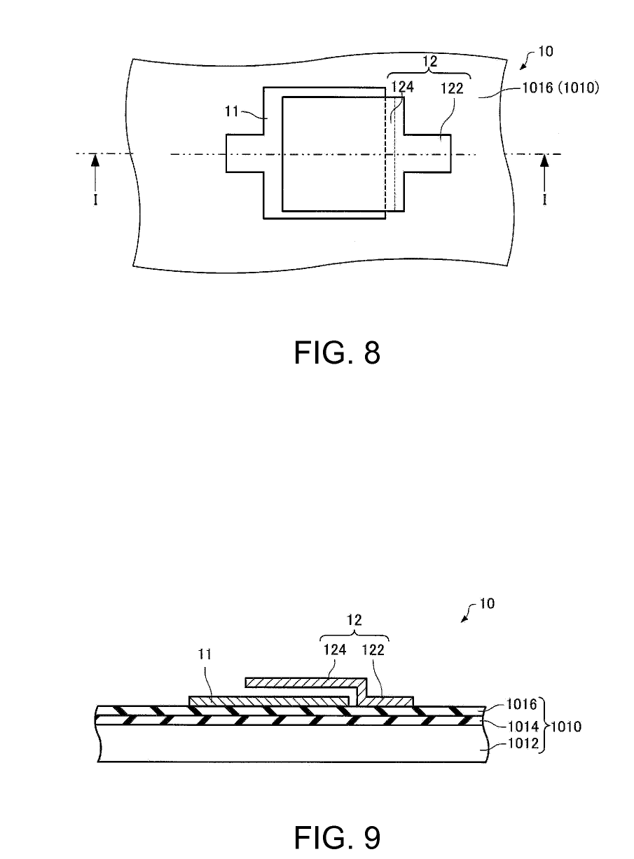

FIG. 8 is a plan view schematically illustrating an example of the configuration of the MEMS vibrator 10. FIG. 9 is a cross-sectional view illustrating the example of the configuration of the MEMS vibrator 10. Meanwhile, FIG. 9 is a cross-sectional view taken along IIIV-IIIV of FIG. 8.

Meanwhile, in the description according to the present embodiment, when a term “upside” is used for a case, for example, another specific object (hereinafter, referred to as “B”) is formed on the “upper side” of a “specific object (hereinafter, referred to as “A”), the term “upper side” is used while including a case where the “B” is directly formed on the “A”, and a case where the “B” is formed on the “A” via another object.

As shown in FIG. 8, the MEMS vibrator 10 includes a first electrode 11 and a second electrode 12 which are provided on the upper side of a substrate 1010. As shown in FIG. 9, the first electrode 11 and the second electrode 12 are arranged with a gap therebetween.

As shown in FIG. 9, the substrate 1010 can include a supporting substrate 1012, a first foundation layer 1014, and a second foundation layer 1016.

For example, a semiconductor substrate, such as a silicon substrate, can be used as the supporting substrate 1012. Various types of substrates, such as a ceramic substrate, a glass substrate, a sapphire substrate, a diamond substrate, and a synthetic resin substrate, may be used as the supporting substrate 1012.

The first foundation layer 1014 is formed on the upper side of the supporting substrate 1012 (in detail, on the supporting substrate 1012). As the first foundation layer 1014, for example, a trench insulation layer, a Local Oxidation of Silicon (LOCOS) insulation layer, or a semi-recess LOCOS insulation layer can be used. The first foundation layer 1014 can electrically separate the MEMS vibrator 10 from other elements (not shown) which are formed on the supporting substrate 1012.

The second foundation layer 1016 is formed on the first foundation layer 1014. As the material of the second foundation layer 1016, for example, silicon nitride can be exemplified.

The first electrode 11 of the MEMS vibrator 10 is formed on the substrate 1010. The shape of the first electrode 11 is, for example, a layer shape or a thin film shape.

The second electrode 12 of the MEMS vibrator 10 is formed to be separated from the first electrode 11. The second electrode 12 includes a supporting section 122 which is formed on the substrate 10 and a beam section 124 which is supported by the supporting section 122 and disposed on the upper side of the first electrode 11. The supporting section 122 is oppositely arranged with a space with respect to, for example, the first electrode 11. The second electrode 12 is formed in a cantilever shape.

When a voltage is applied between the first electrode 11 and the second electrode 12, the beam section 124 can be vibrated using electrostatic force which is generated between the first electrode 11 and the second electrode 12. That is, the MEMS vibrator 10 shown in FIGS. 8 and 9 is the electrostatic-type MEMS vibrator. Meanwhile, the MEMS vibrator 10 may include a coating structure which air seals the first electrode 11 and the second electrode 12 in a depressurization state. Therefore, it is possible to reduce air resistance when the beam section 124 is vibrated.

As the materials of the first electrode 11 and the second electrode 12, for example, polycrystal silicon, to which conductive property is given by doping predetermined impurities, may be exemplified.

Meanwhile, the MEMS vibrator 10 is not limited to the above-described configuration, and various types of well-known MEMS vibrators can be used.

Meanwhile, the above-described embodiments and modification are examples of the invention, and the invention in not limited thereto. For example, a plurality of the embodiments and modification can be arbitrarily combined.

The invention is not limited to the above-described embodiments, and, further, various types of modifications are possible. For example, the invention includes substantially the same configuration (for example, a configuration which has the same function, method, and results or a configuration which has the same object and effect) as the configuration described in the embodiments. Further, the invention includes a configuration which replaces a non-essential section of the configuration described in the embodiments. Further, the invention includes a configuration which has the same operation advantage as the configuration described in the embodiments or a configuration which can accomplish the same object. Further, the invention includes a configuration in which a well-known technology is added to the configuration described in the embodiments.

The entire disclosure of Japanese Patent Application No. 2011-094049, filed Apr. 20, 2011 is expressly incorporated by reference herein.

What is claimed is:

1. A vibration circuit comprising:
a micro electro mechanical systems (MEMS) vibrator which includes a first electrode and a second electrode which are arranged with a gap therebetween;
an amplification section which includes a gain section which has a first input terminal and a first output terminal and of which gain is greater than 1, and a gain restriction section which includes a second input terminal and a second output terminal and of which the gain is less than 1; and
an output terminal which is connected to the first output terminal,
wherein the first electrode is connected to the first input terminal,
wherein the first output terminal is connected to the second input terminal, and
wherein the second output terminal is connected to the second electrode.

2. The vibration circuit according to claim 1, further comprising:
a voltage application section which applies a bias voltage between the first electrode and the second electrode; and
a control section which controls the gain restriction section and the voltage application section,
wherein the control section performs control by associating the gain of the gain restriction section with the bias voltage applied by the voltage application section.

3. The vibration circuit according to claim 2,
wherein the control section performs control such that the gain of the gain restriction section decreases as the bias voltage applied by the voltage application section increases.
